(19) United States
(12) Patent Application Publication
(10) Pub. No.: US 2009/0195416 A1
(43) Pub. Date: Aug. 6, 2009

(54) INPUT ASSEMBLY AND TECHNIQUE FOR IMPROVED DATA ENTRY

(76) Inventor: Michael Goren, Albany, NY (US)

Correspondence Address: HESLIN ROTHENBERG FARLEY & MESITI PC, 5 COLUMBIA CIRCLE, ALBANY, NY, 12203, US

(21) Appl. No.: 12/111,297

(22) Filed: Apr. 29, 2008

Related U.S. Application Data
(60) Provisional application No. 61/025,435, filed on Feb. 1, 2008.

(51) Int. Cl. H03K 17/94

(52) U.S. Cl. 341/20

(57) ABSTRACT

An input assembly and associated technique for dialing mobile phones or otherwise providing input to a device. The device is configured for use with one hand and includes an input assembly for providing input. The input assembly includes a plurality of input controls, each (or a subset thereof) having a neutral position, a primary position and a secondary position; the neutral, primary and secondary positions corresponding to and engaging contacts to input data. When an input control is moved from a neutral position, the input control engages with a contact corresponding to the input control and that position to which the input control has been moved is detected by the device. In response to detecting the primary position, a primary datum corresponding with the input control is entered. In response to detecting the secondary position, a secondary datum corresponding with the input control is entered.

### CROSS-REFERENCE TO RELATED APPLICATIONS

This application claims priority to U.S. Provisional Application No. 61/025,435, entitled “INPUT LEVER ASSEMBLY DEVICE AND METHOD FOR IMPROVED DIALING AND INPUTTING INTO A HANDHELD COMMUNICATION DEVICE”, filed Feb. 1, 2008, which is hereby incorporated herein by reference in its entirety.

### TECHNICAL FIELD

This invention relates, in general, to data entry, and, in particular, to providing a space saving, easy to use capability for entering data in a device.

### BACKGROUND OF THE INVENTION

Certain devices, such as handheld mobile phones, are commonly perceived as slow and frustrating to dial using one hand. Although many handheld devices, such as mobile phones, personal digital assistants, portable computers, remote controls, pagers etc., are relatively small for use with one hand, the functionality of those devices is still awkward.

As an example, keypads provide too many keys that are often small and difficult to reach, target and actuate with one hand. With the rows and columns upon which keys are arrayed, conventional mobile phones are not ergonomic for dialing with the same hand with which they are held. Users frequently make mistakes, especially when it is desirable to dial without having to keep eyes focused on the keys. Further, miniature keyboards configured on mobile phones make it even more difficult to reach and target the tiny keys.

Moreover, when utilizing touch screen phones, users find it even more difficult to dial phone numbers because of the absence of tactile buttons and the need to reach and concentrate on the on-screen keys. Reducing the form factor or increasing the size of the display screen can make input, and specifically dialing a handheld electronic device, cumbersome and inaccurate. Moreover, persons with vision impairments encountering a large number of tiny keys on a keypad that is difficult to dial find it challenging to dial mobile phones.

### SUMMARY OF THE INVENTION

Accordingly, a need exists for a capability that addresses the disadvantages of one-handed input of devices. For example, a need exists for a capability that addresses the difficulties of one-handed input with hard-key keyboards or keypads, and with touch screen keyboards and keypads. A need exists for an easy technique for the tactile targeting and input of data. A need exists for an easier technique to enter data into a mobile phone.

The shortcomings of the prior art are overcome and additional advantages are provided through the provision of an input assembly usable by a device to input data into the device. The assembly includes, for instance, a plurality of contacts; and a plurality of input controls engageable with the plurality of contacts, the plurality of contacts to detect movement of the plurality of input controls, wherein an input control of the plurality of input controls is configured to be moveable to at least a neutral position, a primary position and a secondary position detected by at least one contact of the plurality of contacts, and wherein in response to movement of the input control in a direction of the primary position, a first datum is entered, and in response to movement of the input control in a direction of the secondary position, a second datum is entered, the second datum being different from the first datum, and wherein the datum that is entered is a number from a set of numbers.

Methods relating to one or more aspects of the present invention are also described and claimed herein.

Additional features and advantages are realized through the techniques of the present invention. Other embodiments and aspects of the invention are described in detail herein and are considered a part of the claimed invention.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts a perspective view of an embodiment of a device having a display screen and an integrated input assembly, in accordance with an aspect of the present invention;

FIG. 2 depicts a tip view of an embodiment of an input lever of the input assembly of FIG. 1, the input lever coupled to at least one contact, in accordance with an aspect of the present invention;

FIG. 3 depicts a view of a user holding an embodiment of the device of one aspect of the present invention with the left hand;

FIG. 4 shows a view of a user holding an embodiment of the device with the left hand and actuating the first input lever by moving the first input lever with the thumb, in accordance with an aspect of the present invention;

FIG. 5 depicts a view of an embodiment of the device showing the input levers of the input assembly arrayed on the right side of the device along the x axis for the right thumb to move vertically up and down, in accordance with an aspect of the present invention;

FIG. 5A depicts one embodiment of the numerical values obtained when actuating the levers of the device of FIG. 5, in accordance with an aspect of the present invention;

FIG. 6 depicts a view of an embodiment of the device showing the input levers of the input assembly arrayed on the right side of the device along the y axis for the right thumb to move horizontally side to side, in accordance with an aspect of the present invention;

FIG. 6A depicts one embodiment of the numerical values obtained when actuating the levers of the device of FIG. 6, in accordance with an aspect of the present invention;

FIG. 7 depicts one embodiment of a miniaturized device including an input assembly of one aspect of the present invention; and

FIG. 8 depicts a side view of the device of FIG. 7, in accordance with an aspect of the present invention.

### DETAILED DESCRIPTION OF THE INVENTION

In accordance with one or more aspects of the present invention, a capability is provided to improve one-handed data entry. As an example, a capability is provided to improve one-handed input of data into a device. A device can be any type of electronic communication device or computing device, such as a mobile phone, cell phone, personal digital assistant, portable computer, web appliance, digital remote control, handheld computer, game device, pager or other information devices, as examples.

The device includes, in one embodiment, an optional display and an input assembly used in accordance with an associated technique for providing input, such as, but not limited to, dialing numbers. Examples of embodiments of the present invention are described more fully below.

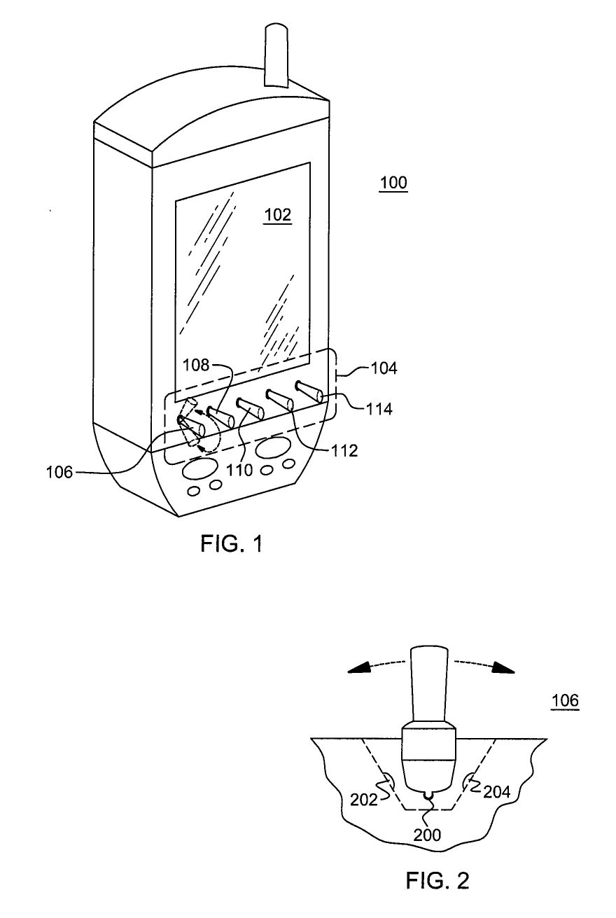

FIG. 1 depicts one example of a perspective view of an embodiment of a handheld device 100, such as a mobile phone, having an optional display screen 102 and an input assembly 104. The arrangement of the input assembly and display screen are proximate as shown in FIG. 1, but can be in any arrangement. Further, in another embodiment, the display screen may be remote from the device. Still referring to FIG. 1, in one embodiment, display screen 102 is optionally a touchscreen. Further, input assembly 104 is, in one example, integrated into the device and includes a plurality of input controls. In this particular example, device 100 includes five (5) input controls, which are levers 106, 108, 110, 112 and 114. However, in other examples, there may be more or less levers than described herein, and further, the controls can be other than levers. The controls may be switches, knobs, or buttons, as further examples. (In succeeding figures, like numbers are used for the same or similar components for convenience.)

FIG. 2 depicts one embodiment of an input lever of the present invention. As one example, input lever 106 (or any other input lever) is engaged with a contact 200 for the neutral position of the lever, and may be engaged with a contact 202 for a primary position and a contact 204 for a secondary position of the lever. Each contact is disposed to be engaged by a user moving the input lever in the direction of the contact. The contacts can be, for instance, electrical contacts or sensors (not shown) to sense the positions of the levers, as examples. Other types of contacts are also possible. The contacts are located within a housing of the device, located on the device or coupled to the device, as examples. The neutral, primary and/or secondary positions can be at other locations than shown.

In one embodiment in which the contacts are sensors, there is one motion sensor which detects motion when the lever is moved. The sensor detects a neutral position, a primary position and a secondary position, in this example.

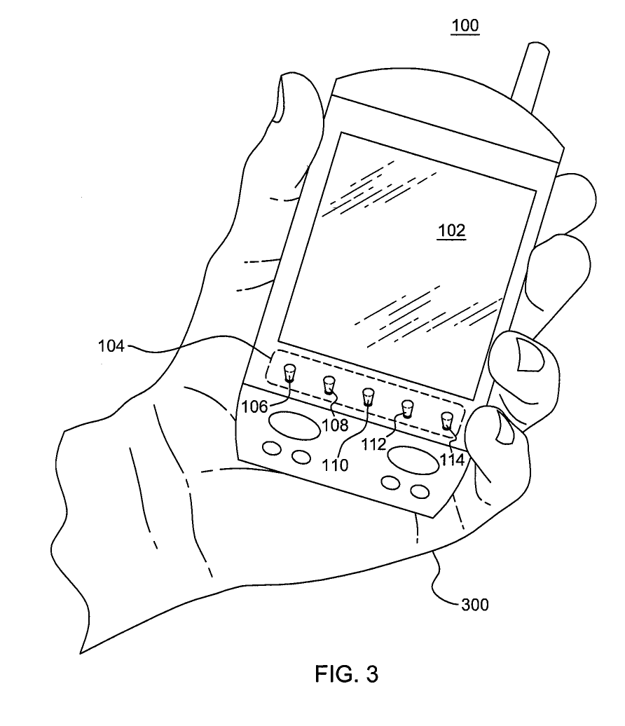

FIG. 3 depicts one embodiment of handheld electronic device 100 being held in the left hand 300 of a user. Device 100 includes, in this example, display screen 102, input assembly 104 for providing input, a processor for receiving inputs from the input assembly (not shown) and an output to the display screen as a result of receiving input from the user (not shown). Each input lever 106, 108, 110, 112 and 114 of input assembly 104 engages at least one contact and each has a neutral position, a primary position and a secondary position, as examples. The neutral, primary and secondary positions corresponding to and engaging contacts to input data, which are optionally displayed on display screen 102.

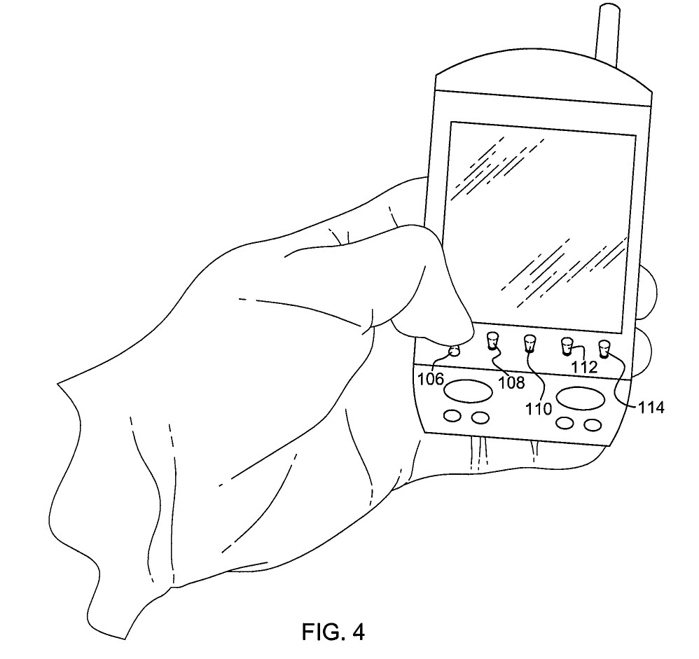

As shown in FIG. 4, each input lever is movable by a user's interaction to input data, such as, for example, a telephone number.

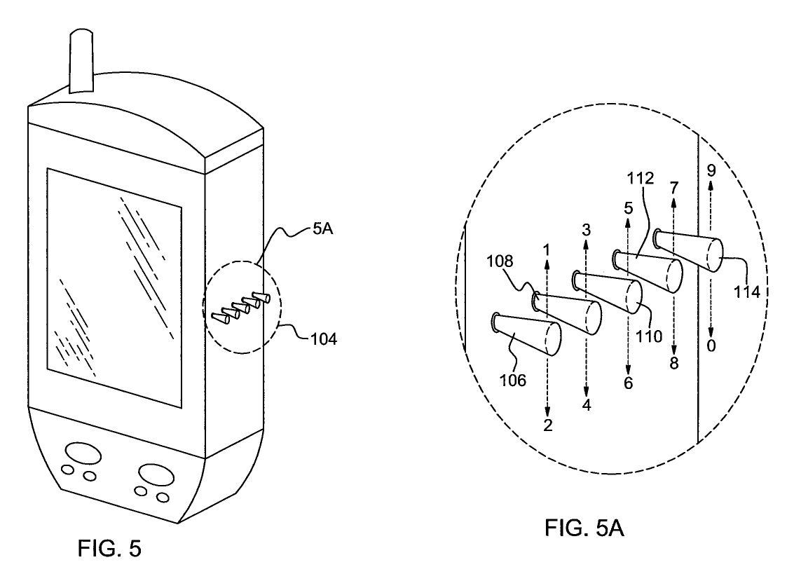

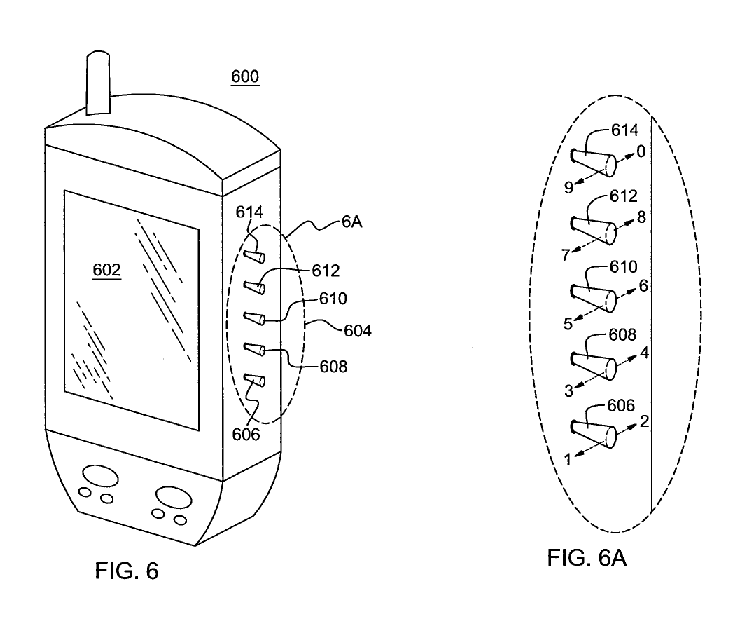

In one embodiment, as shown in FIGS. 1, 3 and 4, the plurality of input levers are disposed horizontally across a handheld electronic device (e.g., on the front or top). In alternative embodiments, the plurality of input levers may also be disposed horizontally on the side of a device, as shown in FIG. 5, or in other locations on the device. Further, the plurality of input levers may be disposed vertically up and down on the side of the device, as shown in FIG. 6, or in other locations on the device. Yet further, the plurality of input levers may be scattered on the device.

In one embodiment, when disposed horizontally, the input levers of the input assembly are moved by a user generally in the vertical direction (as shown in FIGS. 4 and 5A), and when the input levers of the input assembly are arrayed vertically on the device, the input levers are moved generally in a horizontal direction (as shown in FIG. 6A). When one of the input levers is moved by a user from a neutral position, the input lever engages with a contact corresponding to the input lever and that position to which the user has moved the input lever is detected by the device. For example, a signal is sent from the engaged contact to a processor of the device, which indicates the selected position. In response to detecting a user input by the user moving the input lever into a primary position, the primary datum corresponding with the input lever is entered and may be displayed on the display screen, if one is provided. In response to detecting a user input by the user moving the input lever into a secondary position, the secondary datum corresponding with the input lever is entered into the device and may be displayed on the display screen, if one is provided.

As can be understood from FIG. 4, in one embodiment, a user holds in the user's hand an electronic device and enters data by moving the levers. In one example, a ten digit telephone number, such as 1-415-555-1212, is entered, utilizing the input assembly with input levers (or other controls) arrayed horizontally side to side on the electronic device, either on the face of the device, or its side (left or right) or in another location, as desired. The entering of the data is further described with reference to FIG. 5A.

Referring to FIG. 5A, as one particular example in which the above-referenced telephone number is being entered, the user moves first input lever 106 away from the user (i.e., up) to enter the numeral 1, then moves the second input lever 108 toward the user (i.e., down) to enter the numeral 4, then moves first input lever 106 away from the user to enter the numeral 1, then moves the third input lever 110 away from the user to enter the numeral 5, and repeats moving third input lever 110 away from the user three more times to enter the numeral 5 three more times. Then, the user moves first input lever 106 away from the user to enter the numeral 1, then the user moves the first input lever 106 toward the user to enter the numeral 2, then moves the first input lever 106 away from the user to enter the numeral 1, and then moves the first input lever 106 toward the user to enter the numeral 2.

Similarly, referring to FIG. 6, a device 600, which may be the same, similar, or different from device 100, includes an optional display screen 602 and an input assembly 604. Input assembly 604 is similar to input assembly 104, however, the controls (e.g., levers) are arrayed vertically on a side (left or right) of the device. Input assembly 604 includes, for instance, a first input lever 606, a second input lever 608, a third input lever 610, a fourth input lever 612 and a fifth input lever 614. It should be noted that in any of the input assemblies the order of the input levers could be different than described herein (e.g., the first input lever could be at the location of the fifth input lever, etc.).

In this configuration, as one example, a user holds in the user's hand an electronic device and enters data by moving the levers. In one example, a ten digit telephone number, such as 1-415-555-1212, is entered, utilizing the input assembly with input levers arrayed vertically on the device, either on the face of the device, or its side (left or right) or in another location as desired. The entering of the data is further described with reference to FIG. 6A.

Referring to FIG. 6A, in one example, when the input assembly is on the right side of the device and is held by the user's right hand and the above-referenced telephone number is to be entered, the user moves first input lever 606 toward the user (e.g., to the left) to enter the numeral 1, then moves the second input lever 608 away from the user (e.g., to the right) to enter the numeral 4, then moves first input lever 606 toward the user to enter the numeral 1, then moves the third input lever 610 toward the user to enter the numeral 5, and repeats moving third input lever 610 toward the user three more times to enter the numeral 5 three more times. Then, the user moves first input lever 606 toward the user to enter the numeral 1, then moves the first input lever 606 away from the user to enter the numeral 2, then moves the first input lever 606 toward the user to enter the numeral 1, and then moves the first input lever 606 away from the user to enter the numeral 2.

Although in the examples above, telephone numbers are entered, any type of numerical data may be entered. Further, although decimal numbers are described, numbers of any type of numeral system may be entered. Additionally, data other than numbers can be input. For instance, alphabetic characters, alphanumeric characters, symbols, signs, characters, etc. of any language may be input.

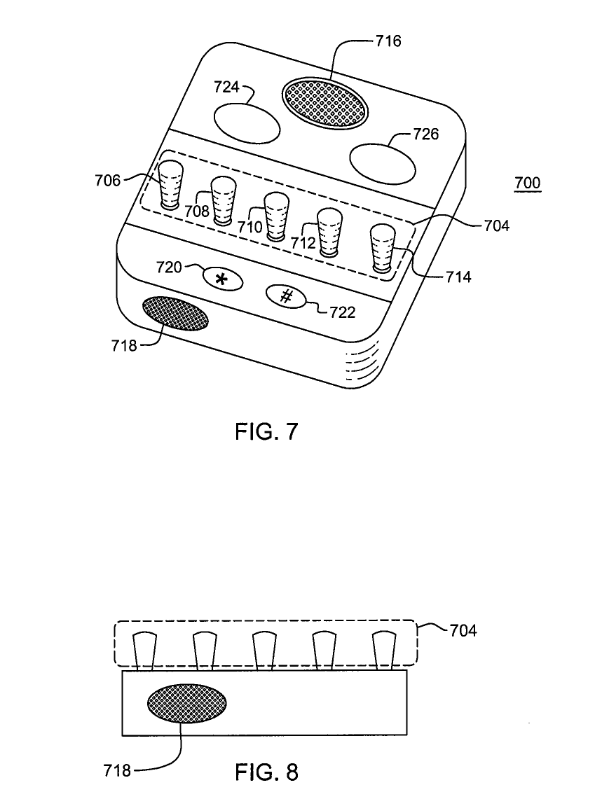

Another embodiment of a device to incorporate and use one or more aspects of the present invention is described with reference to FIG. 7. FIG. 7 depicts one example of a miniaturized device 700, such as a phone, depicted without a display screen. The input levers obviate the need for a full telephone style keypad, and thereby, allow easy dialing using the levers on a very small device.

For example, device 700 is the size of a box of floss or slightly larger than a matchbox (other sizes are also possible). It may or may not have a display screen. In the embodiment depicted in FIG. 7, it does not include a display screen. Device 700 includes, for example, an input assembly 704, which is similar to input assemblies 104 and 604. Input assembly 704 includes, for instance, a first input lever 706, a second input lever 708, a third input lever 710, a fourth input lever 712 and a fifth input lever 714. Device 700 also includes a speaker 716, a microphone 718 and one or more optional inputs. For instance, an * input 720 and a # input 722 is provided. Also, input 724 is included for answering/initiating calls, and input 726 is included for hanging up. Each of these inputs (e.g., 720, 722, 724, 726) is optional. Further, additional, less or other inputs may be provided.

FIG. 8 is a side elevation view of FIG. 7, which depicts, in one embodiment, microphone 718 and input assembly 704.

As described herein, an embodiment of the present invention is directed to lever switches for a user to operate to, for instance, dial a device, such as a mobile phone, or to provide input to other electronic devices. A technique is provided for dialing, inputting, receiving and/or displaying data in response to a user's input. A set of input controls is organized as an array of an input assembly for inputting data by a user on a handheld electronic device. The input controls are movably coupled to the handheld electronic device to engage at least two contacts (e.g., electrical contacts, sensors, etc.). Each input control is associated with a neutral position, a primary position and a secondary position. Input is received from a user who selects an input control from a plurality of input controls. Each primary position and secondary position is respectively associated with its primary or secondary datum from a larger set of data. When a user activates any of the input controls by moving the input control in a direction generally perpendicular with the row or column of input controls arrayed on the electronic device, in response to detecting a movement of the input control to the primary position, a signal is generated to enter as output a primary datum. The primary datum may be stored or displayed on the electronic device. In response to detecting the movement of the input control in the direction of the secondary position, a secondary position signal is generated as output. A secondary datum may be stored or displayed on the electronic device.

In some embodiments, input controls of the input assembly may be organized generally in a row. In other embodiments, the input controls of the input assembly may be organized generally in a column, semi-circle or the like. The controls may be levers, switches, knobs or buttons, as examples.

Further, in some embodiments, the input controls of one or more aspects of the present invention may include a first input control featuring a primary input position for the numeral 1 and a secondary input position for numeral 2; a second input control featuring a primary position for the numeral 3 and a secondary position for numeral 4; a third input control featuring a primary position for numeral 5 and a secondary position for numeral 6; a fourth input control featuring a primary position for numeral 7 and a secondary position for numeral 8; and a fifth input control featuring a primary position for numeral 9 and a secondary position for the zero (0).

In various embodiments, the input assembly is configured to be used with a touch screen, a keyboard, a key pad and/or voice recognition technology as another input source. Further, the input assembly includes an input source for entering a password into the device, as an example.

Yet, further still, a technique for interacting with device (e.g., an electronic device) is provided, which includes, for instance, input controls configured to be selectively moved by a user to neutral, primary and secondary positions, such that when a user moves an input lever to the primary position, a primary datum is entered and optionally displayed, and when a user moves an input control to a secondary position, a secondary datum is entered and optionally displayed.

In one embodiment, resistance is provided to return the control to the neutral position. One or more aspects of the present invention may be implemented with a lever switch or the like or with other types of controls.

Advantageously, the technique of dialing a phone number with a plurality of (e.g., five) levers obviates the need for a large keypad, and therefore, allows small lightweight phones, e.g., the size of headsets, to be utilized. Further, one or more aspects of the present invention obviate the need for a large keypad, by providing a space saving input assembly (e.g., a lever or switch assembly).

Although in the examples provided herein the input assemblies include levers, in other embodiments, the input assemblies can include other controls, such as knobs, buttons, etc. Further, a device can have a mixture of different controls. Yet further, the controls can be used to enter any type of data. As used herein, a datum (or data) includes, but is not limited to, a number in any number system; a character; an alphabetic character; an alphanumeric character; a letter; punctuation; a symbol or sign in any language. The input controls can be used to enter data and/or carry out one or more other functions. They may be arranged for both left-handed and right-handed users.

The device can be any type of device, including, but not limited to, electronic, computing or other devices. The devices may include different, more or less features than described herein. A device may include various keys, buttons, have a hard keyboard or a soft keyboard. The number of input controls may vary in different embodiments.

The disclosed embodiments of the present invention are illustrative and not restrictive and are not meant to be limiting in any manner.

The diagrams depicted herein are just examples. There may be many variations to these diagrams or the steps (or operations) described therein without departing from the spirit of the invention. All of these variations are considered a part of the claimed invention.

Although embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

What is claimed is:

1. An input assembly usable by a device to input data into the device, said input assembly comprising:
a plurality of contacts; and
a plurality of input controls engageable with the plurality of contacts, the plurality of contacts to detect movement of the plurality of input controls, wherein an input control of the plurality of input controls is configured to be moveable to at least a neutral position, a primary position and a secondary position detected by at least one contact of the plurality of contacts, and wherein in response to movement of the input control in a direction of the primary position, a first datum is entered, and in response to movement of the input control in a direction of the secondary position, a second datum is entered, the second datum being different from the first datum, and wherein the datum that is entered is a number from a set of numbers.

2. The input assembly of claim 1, wherein the datum that is entered is part of a telephone number being dialed on the device using one or more input controls of the plurality of input controls.

3. The input assembly of claim 1, wherein the at least one contact comprises a primary contact to detect movement of the input control to the primary position and a secondary contact to detect movement of the input control to the secondary position.

4. The input assembly of claim 1, wherein the at least one contact comprises a sensor to sense movement of the input control to the neutral position, the primary position or the secondary position.

5. The input assembly of claim 1, wherein the plurality of input controls comprises five input levers, wherein a first input lever is associated with the numeral 1 in the primary position and the numeral 2 in the secondary position, a second input lever is associated with the numeral 3 in the primary position and the numeral 4 in the secondary position, a third input lever is associated with the numeral 5 in the primary position and the numeral 6 in the secondary position, a fourth input lever is associated with the numeral 7 in the primary position and the numeral 8 in the secondary position, and a fifth input lever is associated with the numeral 9 in the primary position and zero in the secondary position.

6. The input assembly of claim 1, wherein in response to detecting movement of an input control into the primary position or the secondary position, a selected datum is entered into the device and displayed on a display screen coupled to the input assembly.

7. The input assembly of claim 1, wherein the plurality of input controls comprises more than five controls.

8. The input assembly of claim 1, wherein the input assembly is configured to be used with a touch screen as a second input source.

9. The input assembly of claim 1, wherein said plurality of input controls are disposed generally in patterns of rows or columns.

10. The input assembly of claim 1, wherein the input assembly is configured to be used in conjunction with a keyboard as a second input source.

11. The input assembly of claim 1, wherein the input assembly is configured to be used in conjunction with inputting into the device using voice recognition technology.

12. The input assembly of claim 1, comprising an input source for entering a combination of datum as a password into the device.

13. A method for inputting data in a device, said method comprising:
moving an input control of a plurality of input controls of an input assembly device, said input control being configured to be movable to at least a neutral position, a primary position and a secondary position detected by at least one contact of a plurality of contacts of the input assembly device;
entering a first datum, in response to moving the input control to the primary position; and
entering a second datum, in response to moving the input control to the secondary position, wherein the second datum is different from the first datum, and wherein the datum that is entered is a number from a set of numbers.

14. The method of claim 13, wherein said device is configured for dialing a telephone number, and wherein the entered datum is a portion of the telephone number being dialed into the device.

15. The method of claim 13, wherein the device is a handheld device.

16. The method of claim 13, wherein the device comprises a mobile phone.

17. The method of claim 13, wherein the device comprises a mobile handheld computer.

18. The method of claim 13, wherein the device comprises wireless email capabilities.

19. The method of claim 13, wherein the at least one contact comprises a primary contact to detect movement of the input control to the primary position and a secondary contact to detect movement of the input control to the secondary position.

20. The method of claim 13, wherein the at least one contact comprises a sensor to sense movement of the input control to the neutral position, the primary position or the secondary position.
